(19) United States
(12) Patent Application Publication
(10) Pub. No.: US 2009/0236982 A1
(43) Pub. Date: Sep. 24, 2009

(54) PACKAGING STRUCTURE OF ORGANIC LIGHT-EMITTING DIODE AND METHOD FOR MANUFACTURING THE SAME

(75) Inventors: KOU-CHEN LIU, TAO-YUAN (TW); YUNG-SHIL LIAO, TAO-YUAN (TW); CHIEN-JUNG TSENG, TAO-YUAN (TW)

Correspondence Address: ROSENBERG, KLEIN & LEE, 3458 ELLICOTT CENTER DRIVE-SUITE 101, ELLICOTT CITY, MD, 21043, US

(73) Assignee: CHANG GUNG UNIVERSITY, TAO-YUAN (TW)

(21) Appl. No.: 12/406,323

(22) Filed: Mar. 18, 2009

Related U.S. Application Data
(60) Provisional application No. 61/037,495, filed on Mar. 18, 2008.

(51) Int. Cl. H01J 1/62; C23C 14/34

(52) U.S. Cl. 313/504; 204/192.26; 445/24

(57) ABSTRACT

The present invention discloses a packaging structure of organic light-emitting diode and a method for manufacturing the same. According to the present invention, an organic light emitter layer, which comprises an anode layer, an organic light-emitting layer, and a cathode layer, is provided. A first transparent passivation layer is set on the cathode layer, and has light transmittance greater than 80%. In addition, the first transparent passivation layer has an amorphous or crystalline structure for isolating oxygen and vapor. Because the first transparent passivation layer is sputtered in vacuum at room temperature, it can be applied to flexible printed circuit boards. Furthermore, a second transparent passivation layer is set under a substrate, which is under the organic light emitter layer. Alternatively, a resin layer is set on the first transparent passivation layer or under the second transparent passivation layer as the multi-layer packaging structure.

### REFERENCE TO RELATED APPLICATIONS

This Application is based on Provisional Patent Application Ser. No. 61/037,495, filed 18 Mar. 2009, currently pending.

### FIELD OF THE INVENTION

The present invention relates to a packaging structure and a method for manufacturing the same, and particularly to a packaging structure of organic light-emitting diode and a method for manufacturing the same for protecting the organic light emitter layer from damages by oxygen and vapor.

### BACKGROUND OF THE INVENTION

Owing to their advantages in response time, brightness, viewing angle, lifetime, and low manufacturing cost as well as mature technologies, cathode-ray tubes (CRTs) have dominated display and television markets for several decades. They still own competitive advantages no matter in computer screens or in home entertainment equipments. Although the annual usage of CRTs worldwide has exceeded 200 million units, weight and volume are their major drawbacks. In order to meet the requirements of large-area visual entertainment and of lightness for portability, novel flat-panel display technologies, for example, liquid crystal displays, plasma displays, field emission displays, vacuum fluorescent displays, light-emitting diodes, or electroluminescent displays, were developed continually within the past ten years.

A traditional CRT uses accelerated electrons to bombard the fluorescent powder on the screen to emit light. For larger area of the display, the CRT has to become larger so that electrons can gain sufficient energy to stimulate the fluorescent powder. Thereby, the volume of the television becomes large and bulky. On the contrary, for a flat-panel display, when the area goes larger, the volume thereof will not change as significantly as a CRT. Color liquid crystal displays are applied to portable displays successfully, and are gradually replacing CRT's market share in monitors of desktop computers.

The light-emitting principle of organic electroluminescence is similar to that of a light-emitting diode using inorganic materials, and can be roughly divided into two categories: small-molecule organic light-emitting diode and large-molecule organic light-emitting diode. The reason why the organic electroluminescence technology is widely popular is that a flat-panel display made using this technology satisfies stringent requirements for an ideal display, which has the major characteristics of:
1. Thin-film device, capable of being fabricated on large-area substrates;
2. Low-temperature process, capable of fabricated on any substrates (including plastic substrates);
3. Fast response time (about 0.000001 second) and high response speed (more than one hundred times faster than a liquid crystal display);
4. Capability of manufacturing devices for the three primary colors (red, green, and blue), and also for white light;
5. Low operating voltage (less than 10 volts. At 4 volts, the luminance can reach 300 cd/meter squared);
6. High luminance efficiency (greater than 10 lm/Watt);
7. High brightness (can be greater than 100,000 cd/meter squared);
8. Self-luminescence, wide viewing angle (about 160 degree, and can be made almost reaching 180 degrees) (a liquid crystal display is not self-luminescent with a viewing angle of about 120 degrees);
9. Flexibility; and
10. Simpler fabrication processes with low cost potentials.

When an organic light-emitting diode is forward biased, the energy of the applied voltage drives electrons and holes to inject into the semiconductor device from negative and positive electrodes, respectively. When they meet in conduction, they will recombine and form electron-hole complexes. At this moment, the state of electrons will return to stable low energy states from excited high energy states. The energy differences between the energy states will be released in the forms of photons or heat, where the photons in frequencies of visible light can be used for display function. Because the emitted photons are converted from the released energy, which is the energy-state difference of the material, we can choose appropriate materials as the light-emitting layer. Alternatively, we can dope dyes in the light-emitting layer for giving the desired color. According to researches, it is gradually understood that the characteristics of the organic material greatly influence the optoelectric performance of a device. The structure of the device has also developed from double layers to multiple layers. A novel structure includes an indium-tin-oxide transparent glass substrate, a hole injection layer, a hole transport layer, a light-emitting layer, an electron transport layer, and metal electrodes. In order to enhance light-emitting efficiency, the injection of electrons and holes has to increase. Thereby, at cathode, metals with low work functions are usually chosen to help injection of electrons. However, metals with low work functions are relatively active, easy to oxidizing with vapor and hence damaging the cathode.

According to the present invention, radio-frequency sputtering is used to sputter a transparent passivation layer onto the cathode of the organic light emitter layer for protecting it from damages by oxygen and vapor. In addition, because the process is performed at room temperature, it can be applied to flexible printed circuit boards.

### SUMMARY

An objective of the present invention is to provide a packaging structure of organic light-emitting diode and a method for manufacturing the same, which sputters a transparent passivation layer in vacuum and at room temperature onto the cathode of an organic light emitter layer for isolating it from oxygen and vapor.

Another objective of the present invention is to provide a packaging structure of organic light-emitting diode and a method for manufacturing the same, which uses a resin layer on the transparent passivation layer for enhancing the isolation effect from oxygen and vapor.

In order to achieve the objectives and effects described above, the present invention discloses a packaging structure of organic light-emitting diode and a method for manufacturing the same. According to the present invention, an organic light emitter layer, which comprises an anode layer, an organic light-emitting layer, and a cathode layer, is provided. A first transparent passivation layer is set on the cathode layer, and has the effect of blocking ultraviolet rays with light transmittance greater than 95% in the visible spectrum. In addition, the first transparent passivation layer has an amorphous or crystalline structure for isolating oxygen and vapor. Because the first transparent passivation layer is sputtered in vacuum at room temperature, it can be applied to flexible printed circuit boards.

Furthermore, a second transparent passivation layer is set under a substrate, which is under the organic light emitter layer. Alternatively, a resin layer is set on the first transparent passivation layer or under the second transparent passivation layer as the multi-layer packaging structure.

### BRIEF DESCRIPTION OF THE DRAWINGS

FIG. 1 shows a structural schematic diagram according to a preferred embodiment of the present invention;

FIG. 2 shows a structural schematic diagram of zinc oxide according to a preferred embodiment of the present invention;

FIG. 3 shows a structural schematic diagram according to another preferred embodiment of the present invention;

FIG. 4 shows a structural schematic diagram according to another preferred embodiment of the present invention;

FIG. 5 shows a fabrication flowchart according to a preferred embodiment of the present invention;

FIG. 6 shows XRD pattern of ZnO, ITO and IZO according to a preferred embodiment of the present invention;

FIG. 7 shows spectrum of I-V characteristics of only encapsulated glass PLEDs and ZnO/UV-curable resin passivated PLEDs according to a preferred embodiment of the present invention;

FIG. 8 shows spectrum of L-I characteristics and efficiency of only encapsulated glass PLEDs and ZnO/UV-curable resin passivated PLEDs.which were measured from top and bottom side. according to a preferred embodiment of the present invention;

FIG. 9 shows spectrum of the transmittance of reference cathode and encapsulated passivation layer with ZnO/UV-curable resin on a glass according to a preferred embodiment of the present invention;

FIG. 10 shows spectrum of the comparison of the normalized EL spectra of the TEPLEDs passivated with ZnO/UV-curable resin and reference device according to a preferred embodiment of the present invention;

FIG. 11 shows spectrum of the comparison of the normalized luminance and operating voltage vs operating time of PLEDs passivated with ZnO/UV-curable resin, non-encapsulated device and a reference device according to a preferred embodiment of the present invention;

FIG. 12a shows photographs of the emitting areas of the non-encapsulated device;

FIG. 12b shows photographs of the emitting areas of the encapsulated device with glass lid (reference device); and

FIG. 12c shows photographs of the emitting areas of the passivated device with ZnO/UV-curable according to another preferred embodiment of the present invention.

### DETAILED DESCRIPTION

In order to make the structure and characteristics as well as the effectiveness of the present invention to be further understood and recognized, the detailed description of the present invention is provided as follows along with preferred embodiments and accompanying figures.

FIG. 1 shows a structural schematic diagram according to a preferred embodiment of the present invention. As shown in the figure, the packaging structure for organic light-emitting diode according to the present invention comprises a substrate 10, an organic light emitter layer 15, and a first transparent passivation layer 50. The organic light emitter layer 15 is set on the substrate 10, and comprises sequentially an anode layer 20, an organic light-emitting layer 30, and a cathode layer 40. The first transparent passivation layer 50 is ser on the cathode layer 40.

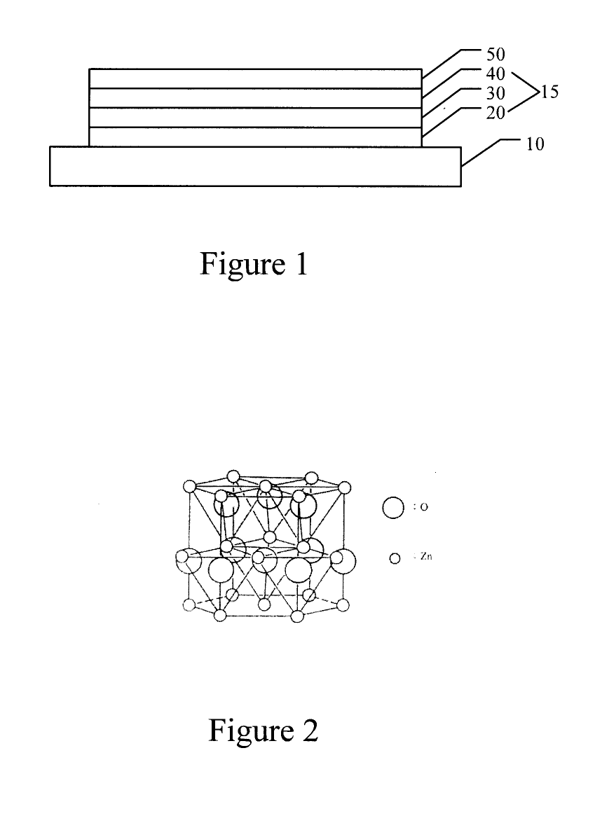

The first transparent passivation layer 50 has the function of isolating oxygen and vapor, and thereby materials with amorphous or crystalline structures are adopted. According to the present preferred embodiment, zinc oxide (ZnO) is used as an example. ZnO is a well-known piezoelectric material with a hexagonal crystal structure (as shown in FIG. 2). The thin-film characteristics of ZnO are usually influenced by preparation parameters, such as deposition method, deposition pressure, substrate temperature, substrate materials, and thin-film thickness. Sintered ZnO target is more suitable than metal zinc target in preparing ZnO thin films with c-axis preferred orientation. According to technical literature, because ZnO thin films lack oxygen vacancies, ZnO thin films with relatively higher resistivity (1˜100Ω-cm) need to be crystalline for having preferable properties, such as high hardness, high wear resistance, excellent thermal and chemical stability, high insulation, and superior barrier-layer characteristics for diffusion, for being used as passivation layers, light filters, or multilayer interference membranes.

Thereby, a ZnO thin film can act as a barrier layer for vapor. It can also help to guide light of a device, enhancing visible-light transmittance. In addition, ZnO has excellent effect of blocking ultraviolet rays with light transmittance greater than 95% in the visible spectrum. The refractivity of ZnO (n=2) can match with the cathode layer 40 for enhancing light extraction efficiency.

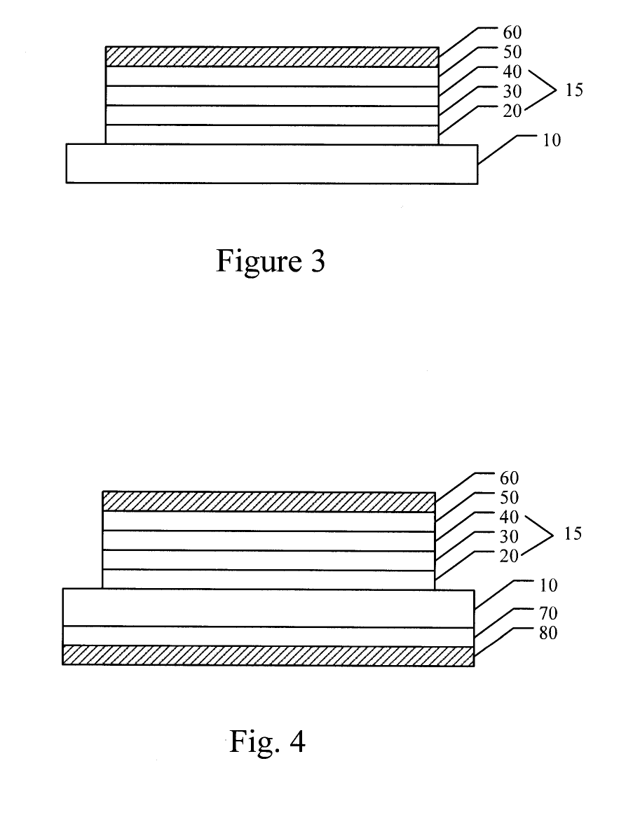

FIG. 3 shows a structural schematic diagram according to another preferred embodiment of the present invention. As shown in the figure, according to another preferred embodiment of the present invention, a first resin layer 60 is further set on the first transparent passivation layer 50 to form a multilayer packaging structure and thus enhancing isolation efficiency from vapor and oxygen. Because the material of the first transparent passivation layer 50 is ZnO, which can absorb ultraviolet rays, the first resin layer 60 can use ultraviolet-hardened resin.

FIG. 4 shows a structural schematic diagram according to another preferred embodiment of the present invention. As shown in the figure, according to another preferred embodiment of the present invention, a second transparent passivation layer 70 and the first transparent passivation layer 50 are set under the substrate 10, which is under the organic light emitter layer 15, and on the cathode layer 40, respectively. In addition, the first resin layer 60 and a second resin layer 80 are set on the first transparent passivation layer 50 and under the second transparent passivation layer 70, respectively, to form a multilayer packaging structure.

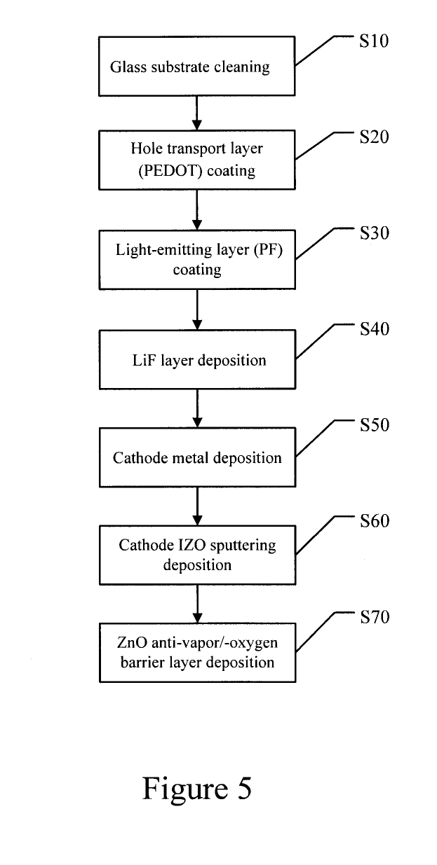

FIG. 5 shows a fabrication flowchart according to a preferred embodiment of the present invention. As shown in the figure, the method for manufacturing the packaging structure of organic light-emitting diode according to the present invention comprises steps of:
S10, glass substrate cleaning: The cleaning is done by ultrasonic vibrator at temperatures around 50° C.-60° C. The glass substrate is cleaned sequentially by DI (deionized) water, acetone, DI water, isopropanol, and DI water. Finally, spray the glass substrate dry by nitrogen gas.
S20, hole transport layer (PEDOT) coating: Use spin coating to deposit the hold conduction layer onto the ITO substrate. Then bake in the glove box at 120° C. for 15 minutes for removing the solvent of the layer.
S30, light-emitting layer (PF) coating: Use spin coating to deposit the light-emitting layer onto the PEDOT layer. Then bake in the glove box at 120° C. for 30 minutes for removing the solvent of the layer.
S40, LiF layer deposition: Vacuum the chamber below 5.0E-6 torr. Use effusion cell to heat LiF material and vapor deposit to the sample surface. Because effusion cell has excellent temperature control for heating the material uniformly, the film thickness of LiF can be controlled effectively. For not deteriorating device performance due to oxidation on the cathode metal, metals with relative high stability are generally chosen. The work functions of such metals are usually very high, unfavorable for electron injection. Thereby, the purpose of the LiF layer is to lower energy barrier for electron injection by reaction with the metal, and hence enhancing light-emitting efficiency of the device.
S50, cathode metal deposition: Use thermal evaporation to deposit cathode metal. Metals with excellent conductivity are preferable for reducing resistance of the whole cathode structure. Thereby, the probability of election injection into the organic layer is increased, and thus enhancing light-emitting efficiency of the device.
S60, cathode IZO sputtering deposition: Deliver the sample having the electron transport layer into the sputtering chamber. Vacuum the chamber to below 5.0E-6 torr. Use low-power DC power (40˜70 Watt) to sputtering deposit IZO cathode for not damaging the underlying organic layer by physical bombardment of sputtering.
S70, ZnO anti-vapor/-oxygen barrier layer deposition: At a high-vacuum environment (5.0E-6 torr), sputter directly an inorganic ZnO anti-vapor/-oxygen barrier layer on the device with cathode structure LiF/Ag(1 nm), Al₂O₃/IZO, or ITO, for reducing vapor or oxygen covering on the cathode structure.

Furthermore, the substrate temperature for depositing the ZnO thin film is controlled at room temperature for avoiding damages on the device caused by thermal processes. Beside, the room-temperature process can be applied to flexible substrates for manufacturing flexible light-emitting displays. Fabrication conditions, such as temperature and pressure, will determine if ZnO is amorphous or crystalline.

### Result and Discussion

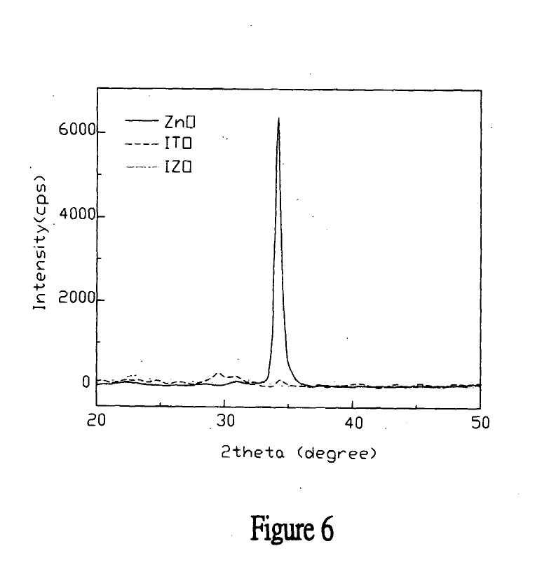

The X-ray diffraction (XRD) spectra show in FIG. 6. ZnO, ITO and IZO thin films deposited on glass at room temperature. The crystallinity is demonstrated in the X-Ray Diffraction measurements. T he diffraction patterns of the ZnO thin film clearly displays a highly ordered structure with the distinctive peak at 2θ=34.24°. In addition, the XRD measurement of the ITO film indicates more crystalline than IZO film. This data can explain our experimental works that a passivation layer of crystalline ZnO cannot directly deposit onto the ITO cathode. To prevent ZnO film crack, a thin AlB₂BOB₃B layer has to be inserted between a ZnO and ITO layer. This thin AlB₂BOB₃B layer cause light emitting from top surface lessening. On the contrary, a ZnO passivation layer aptly places onto the IZO cathode without any film delaminating and decreasing light output from top surface.

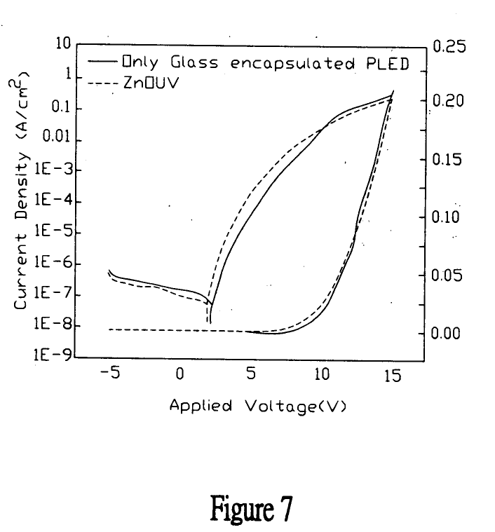

FIG. 7 shows the current density-voltage (I-V) characteristics of the PLED device with IZO cathode encapsulated with glass and the ZnO/UV-curable resin films. Both two devices show similar electrical behavior for instance turn on voltage and leakage current. According to Kim et al. reported, the effect of sputtering damage can be observed from the leakage current at reverse bias. However, in our experiment data, all devices keep the same low leakage current density under reverse bias. It can be explained that one more processes of ZnO layer sputtering does not cause further damage.

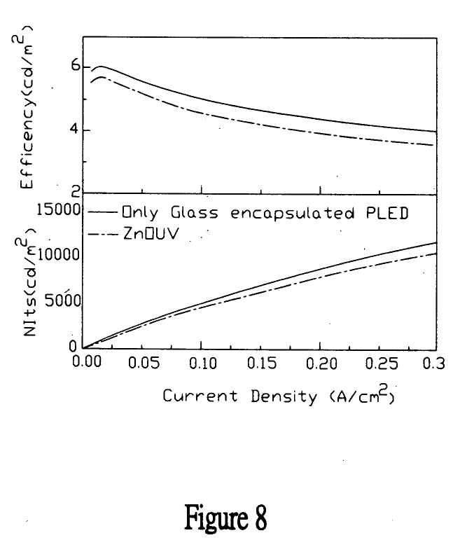

FIG. 8 displays the total brightness and current efficiency obtained by summation of the top and bottom light outputs of the full transparent PLEDs. The light intensity increases linearly with current density. This PLED device encapsulated with ZnO/UV-curable resin has less current efficiency. In Table 1, compared with the device encapsulated by glass, the light intensity emitting from top side illustrate 10% higher than that of the device encapsulated with ZnO/UV-curable resin but the light intensity emitting from bottom side indicate only 5% higher than that of the device encapsulated with ZnO/UV-curable resin. The Table 1 is shown below,

TABLE 1

| | 0.05 A/cm². | | 0.3 A/cm². | |
|---|---|---|---|---|
| Sample Structure | TOP | BOTTOM | TOP | BOTTOM |
| Encapsulated Glass(reference | 1444 | 1510 | 5810 | 6130 |
| device) | | | | |
| Encapsulated Passivation | 1240 | 1490 | 4860 | 5850 |
| Layer Device | | | | |

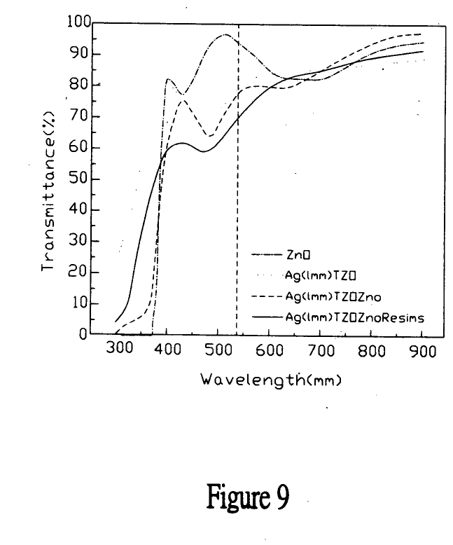

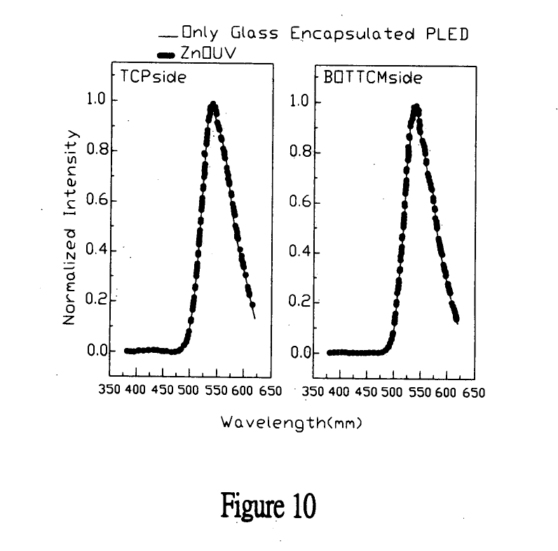

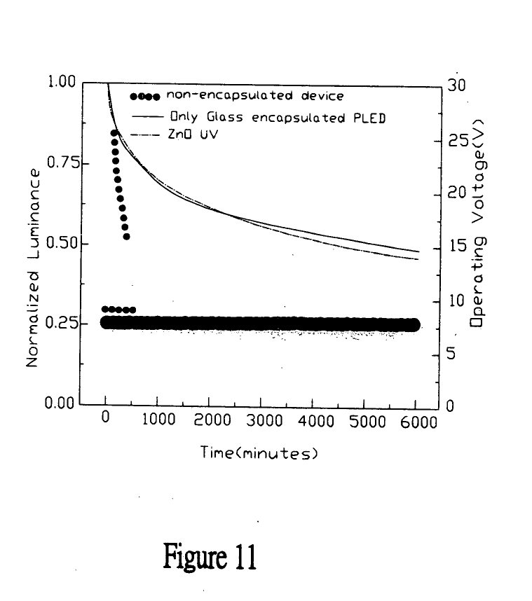

The difference of luminance emitting from bottom side of two devices can attribute to UV light damaged PFO layer during UV-curable resin curing process. However, the luminance emitting from top side difference clearly results from UV-curable resin layer absorption 10% light that consists of the result in FIG. 9. The normalized EL spectra of the PLEDs passivated with a ZnO/UV-curable resin films and reference device have been measured under 1 mA current in FIG. 10. The EL spectra of the top and bottom side from both devices demonstrate almost same characteristic. This result indicates that the addition passivation layer do not influence the EL characteristic of the device. It means that the encapsulation layer will not produce series micro cavity effect. FIG. 11 shows the rate of degradation with difference encapsulated layer for the full transparent PLED devices. Total three devices were used to realize the encapsulated layer effect. The first one without any encapsulated layer has very short lifetime and sharply decreasing in the luminance. The device performance seriously decay related to organic layers direct intrusion by moisture and oxygen and resulting larger operating voltage (˜8.8V). The second device encapsulated a glass (reference device) and the third device passivated with ZnO/UV-curable resin both show similar life time approximately 100 hours in atmospheric condition under dc constant current density of 6.6 mA/cmP2 (an initial luminance of 190 cd/mP2P)and operating voltage kept around 7.5V. This indicates that using ZnO/UV-curable resin as a passivated layer has the same capability to prevent oxygen and moisture permeation.

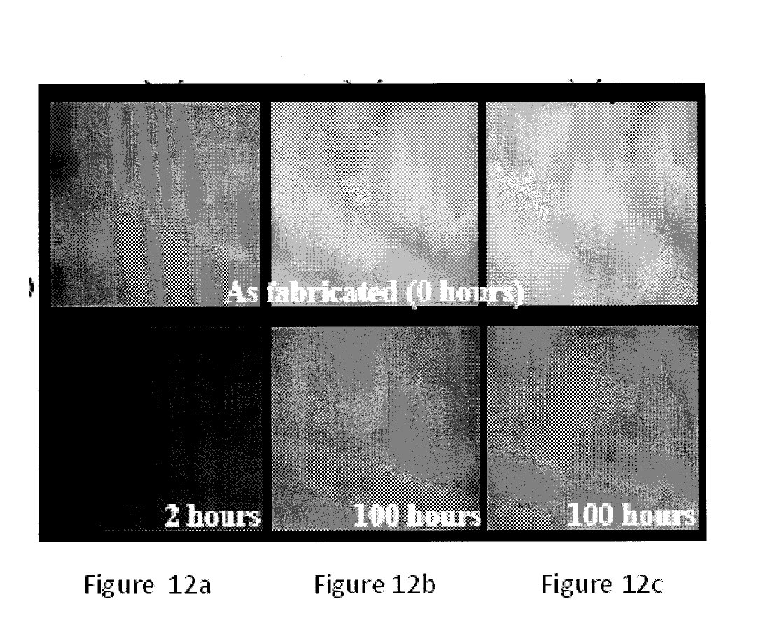

FIG. 12a-12c shows optical images of the electroluminescence with time for all devices. We can clearly find the dark spots were formed after two hours in FIG. 12a. The FIG. 12a shows the moisture or oxygen permeation progress through the edge structure and the performance was poor when the device was stored in air condition. The device was glass encapsulated shown no dark spots formation after 100 hours in FIG. 12b. However, the ZnO/UV-curable resin encapsulated device, the pixel has been kept almost clear over 100 hours as shown in FIG. 12c. This observation is consistent with our lifetime results.

In summary, we demonstrated the ZnO/UV-curable resin passivation layer which could effectively protect the device that showed similar electrical behavior to the glass encapsulated device, indicating that its fabrication process for forming the passivation layer did not influence the performance of the device apparently. The lifetime of both devices was almost same and the optical images of the electroluminescence with time did not find dark spots formed. However, ZnO/UV-curable rein (inorganic/organic multilayer) performs the characteristics of flexible and light which develop the applications of PLEDs in the field of flexible flat panel displays.

Accordingly, the present invention conforms to the legal requirements owing to its novelty, non-obviousness, and utility. However, the foregoing description is only a preferred embodiment of the present invention, not used to limit the scope and range of the present invention. Those equivalent changes or modifications made according to the shape, structure, feature, or spirit described in the claims of the present invention are included in the appended claims of the present invention.

1. A packaging structure of organic light-emitting diode, comprising:
a substrate;
an organic light emitter layer, comprising an anode layer, an organic light-emitting layer, and a cathode layer set sequentially on the substrate; and
a first transparent passivation layer, set on the cathode layer for blocking ultraviolet rays.

2. The packaging structure of organic light-emitting diode of claim 1, wherein the first transparent passivation layer has an amorphous or crystalline structure.

3. The packaging structure of organic light-emitting diode of claim 2, wherein the first transparent passivation layer has a hexagonal lattice structure.

4. The packaging structure of organic light-emitting diode of claim 1, wherein the material of the first transparent passivation layer is zinc oxide.

5. The packaging structure of organic light-emitting diode of claim 1, wherein the first transparent passivation layer has light transmittance greater than 80% in the visible spectrum.

6. The packaging structure of organic light-emitting diode of claim 1, and further comprising a flexible circuit board set under the substrate.

7. The packaging structure of organic light-emitting diode of claim 1, and further comprising a second transparent passivation layer set under the substrate.

8. The packaging structure of organic light-emitting diode of claim 7, wherein the material of the second transparent passivation layer is zinc oxide.

9. The packaging structure of organic light-emitting diode of claim 7, wherein the second transparent passivation layer has an amorphous or crystalline structure.

10. The packaging structure of organic light-emitting diode of claim 9, wherein the second transparent passivation layer has a hexagonal lattice structure.

11. The packaging structure of organic light-emitting diode of claim 7, wherein a first resin layer is further set on the first transparent passivation layer; and a second resin layer is further set under the second transparent passivation layer.

12. The packaging structure of organic light-emitting diode of claim 8, wherein the material of the first and second resin layers is ultraviolet-hardened resin.

13. The packaging structure of organic light-emitting diode of claim 12, and further comprising a flexible circuit board set under the second resin layer.

14. The packaging structure of organic light-emitting diode of claim 1, and further comprising a first resin layer set on the first transparent passivation layer.

15. The packaging structure of organic light-emitting diode of claim 14, wherein the material of the first resin layer is ultraviolet-hardened resin.

16. The packaging structure of organic light-emitting diode of claim 14, and further comprising a flexible circuit board set under the substrate.

17. A method for manufacturing a packaging structure of organic light-emitting diode, comprising steps of:
providing an organic light emitter layer, comprising, from bottom up, an anode layer, an organic light-emitting layer, and a cathode layer; and
sputtering a first transparent passivation layer on the cathode layer in vacuum at room temperature.

18. The method for manufacturing a packaging structure of organic light-emitting diode of claim 17, wherein the pressure in the step of sputtering the first transparent passivation layer on the cathode layer in vacuum at room temperature is 5.0E-6 torr.

19. The method for manufacturing a packaging structure of organic light-emitting diode of claim 17, wherein the sputtering method in the step of sputtering the first transparent passivation layer on the cathode layer in vacuum at room temperature is radio-frequency sputtering.
